(19) United States
(12) Patent Application Publication
(10) Pub. No.: US 2026/0344088 A1
(43) Pub. Date: Oct. 29, 2026

(54) PIXEL ISOLATION STRUCTURE FOR IMAGE SENSOR

(71) Applicant: Taiwan Semiconductor Manufacturing Company, Ltd., Hsinchu (TW)

(72) Inventors: Tzu-Jui Wang, Fengshan City (TW); Chi-Hsien Chung, New Taipei City (TW); Shih-Min Huang, Hsinchu County (TW); Chen-Jong Wang, Hsin-Chu (TW); Dun-Nian Yaung, Taipei City (TW); Chia-Chi Hsiao, Tianzhong Township (TW)

(21) Appl. No.: 19/721,313

(22) Filed: Jun. 26, 2026

Related U.S. Application Data
(63) Continuation of application No. 18/676,841, filed on May 29, 2024.

(51) Int. Cl. H10F 39/00

(52) U.S. Cl. CPC H10F 39/807; H10F 39/011

(57) ABSTRACT

An image sensor including a photodetector in a semiconductor substrate. A floating node is in the semiconductor substrate and beside the photodetector. A transfer gate is over and between the photodetector and the floating node. A deep trench isolation (DTI) structure extends into the semiconductor substrate from a backside of the semiconductor substrate. A shallow trench isolation (STI) structure extends into the semiconductor substrate from a frontside of the semiconductor substrate and over the DTI structure. The DTI structure extends into the semiconductor substrate to a first depth from the backside. The DTI structure extends into the STI structure to a second depth from the backside different than the first depth.

### REFERENCE TO RELATED APPLICATION

This Application is a Continuation of U.S. application number Ser. No. 18/676,841, filed on May 29, 2024, the contents of which are hereby incorporated by reference in their entirety.

### BACKGROUND

Complementary metal-oxide semiconductor (CMOS) image sensors are used in a wide range of modern-day electronic devices, such as, for example, cameras, tablets, smart phones, and so on. CMOS image sensors may be front-side illuminated (FSI) or back-side illuminated (BSI). CMOS image sensors include photodetectors and isolation structures to isolate photodetectors from neighboring photodetectors.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A, FIG. 1B, FIG. 1D, FIG. 1E, and FIG. 1F illustrate various cross-sectional views of some embodiments of an image sensor including shallow trench isolation (STI) structures on a deep trench isolation (DTI) structure.

FIG. 1C illustrates an enlarged cross-sectional view of some embodiments of a portion of the image sensor of FIG. 1B.

FIG. 1G illustrates a top view of some embodiments of the image sensor of FIGS. 1A-1F.

FIG. 2A, FIG. 2B, FIG. 2D, FIG. 2E, and FIG. 2F illustrate various cross-sectional views of some embodiments of the image sensor of FIGS. 1A-1G further including an isolation region.

FIG. 2C illustrates an enlarged cross-sectional view of some embodiments of a portion of the image sensor of FIG. 2B.

FIG. 2G illustrates a top view of some embodiments of the image sensor of FIGS. 2A-2F.

FIG. 3A illustrates a cross-sectional view of some embodiments of the image sensor of FIGS. 2A-2G in which a first STI structure has three lower surfaces at three different depths.

FIG. 3B illustrates a top view of some embodiments of the image sensor of FIG. 3A.

FIG. 4A and FIG. 4B illustrate cross-sectional views of some embodiments of the image sensor of FIGS. 2A-2G further including a pickup region.

FIG. 4C illustrates a top view of some embodiments of the image sensor of FIG. 4A and FIG. 4B.

FIG. 5A and FIG. 5B illustrate cross-sectional views of some embodiments of the image sensor of FIGS. 2A-2G in which a floating node is disposed at an intersection where one wall of the DTI structure intersects with another wall of the DTI structure.

FIG. 5C illustrates a top view of some embodiments of the image sensor of FIG. 5A and FIG. 5B.

FIG. 6A illustrates a cross-sectional view of some other embodiments of the image sensor of FIGS. 2A-2G further including a pickup region.

FIG. 6B illustrates a top view of some embodiments of the image sensor of FIG. 6A.

FIG. 7A and FIG. 7B illustrate cross-sectional views of some embodiments of the image sensor of FIGS. 2A-2G in which the DTI structure is laterally spaced from the floating node.

FIG. 7C illustrates a top view of some embodiments of the image sensor of FIG. 7A and FIG. 7B.

FIG. 8 and FIG. 9 illustrate top views of some embodiments of the image sensor of FIGS. 2A-2G in which a pixel includes more than one photodetector region.

FIGS. 10A, 10B, 10C, 10D through FIGS. 16A, 16B, 16C, 16D illustrate various views of some embodiments of a method for forming an image sensor including STI structures on a DTI structure.

FIG. 17 illustrates a flow diagram of some embodiments of a method for forming an image sensor including STI structures on a DTI structure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An image sensor includes a photodetector in a semiconductor substrate. A floating node is in the semiconductor substrate and beside the photodetector. A transfer gate is over and between the photodetector and the floating node. A deep trench isolation (DTI) structure extends into the semiconductor substrate from a backside of the semiconductor substrate and surrounds the photodetector. The DTI structure extends directly under the floating node.

In some examples, to avoid damaging the floating node, the depth of the DTI structure (as measured from the backside of the substrate toward the frontside of the substrate) is reduced so that the top surface of the DTI structure is spaced from the bottom of the floating node. An isolation region of the substrate extends from the frontside of the substrate toward the backside and to the top of the DTI structure so that together the DTI structure and the isolation region electrically isolate the photodetector from neighboring photodetectors. Because the depth of the DTI structure is reduced (e.g., the distance between the top surface of the DTI structure and the frontside of substrate is increased), the depth of the isolation region (as measured from the frontside toward the backside of the substrate) is increased to ensure the isolation region reaches the DTI structure. However, increasing the depth of the isolation region may cause the width of the isolation region to be increased, which may reduce a full well capacity (FWC) of the photodetector.

To address this challenge, in some examples the depth of the DTI structure is increased except under the floating node. By increasing the depth of the DTI structure (as measured from the backside), the depth of the isolation region (as measured from the frontside) can be decreased. Thus, the width of the isolation region may be decreased and hence a FWC of the photodetector may be increased. However, when the depth of the DTI structure is increased, portions of the DTI structure may extend through the frontside of the substrate. This may cause damage which may reduce the performance and/or reliability of the image sensor.

In various embodiments of the present discourse, shallow trench isolation (STI) structures extend into the semiconductor substrate from the frontside of the semiconductor substrate directly over the DTI structure to block the DTI structure from extending through the frontside of the substrate. The DTI structure extends into the STI structures but not through the tops of the STI structures. Thus, damage can be reduced.

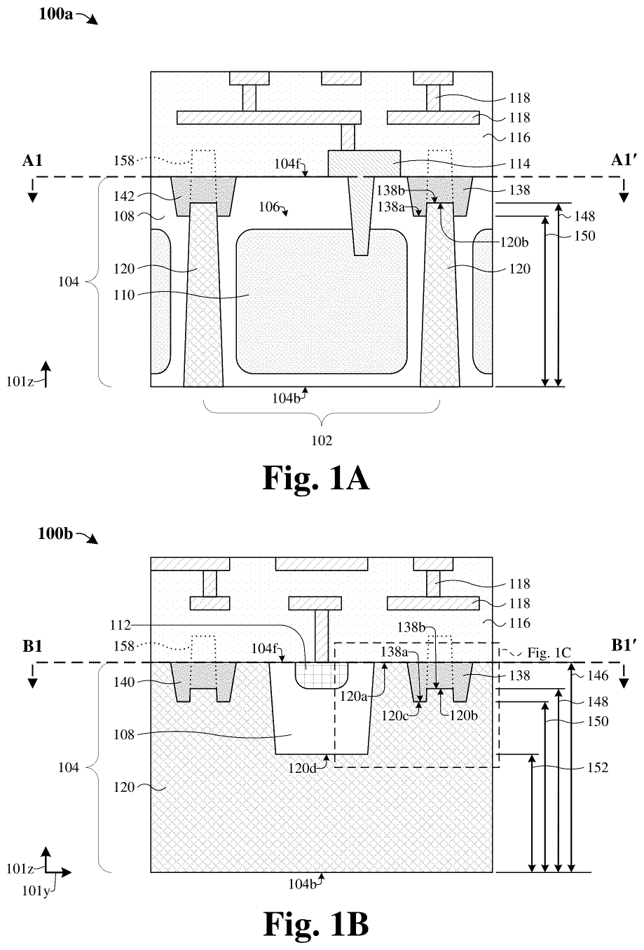

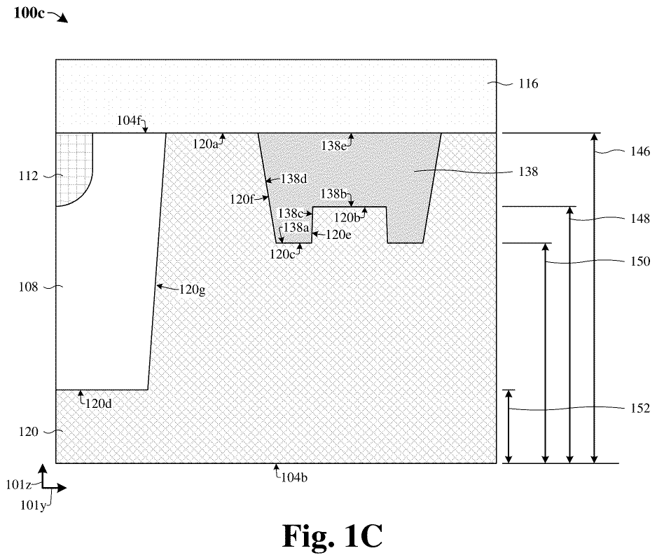

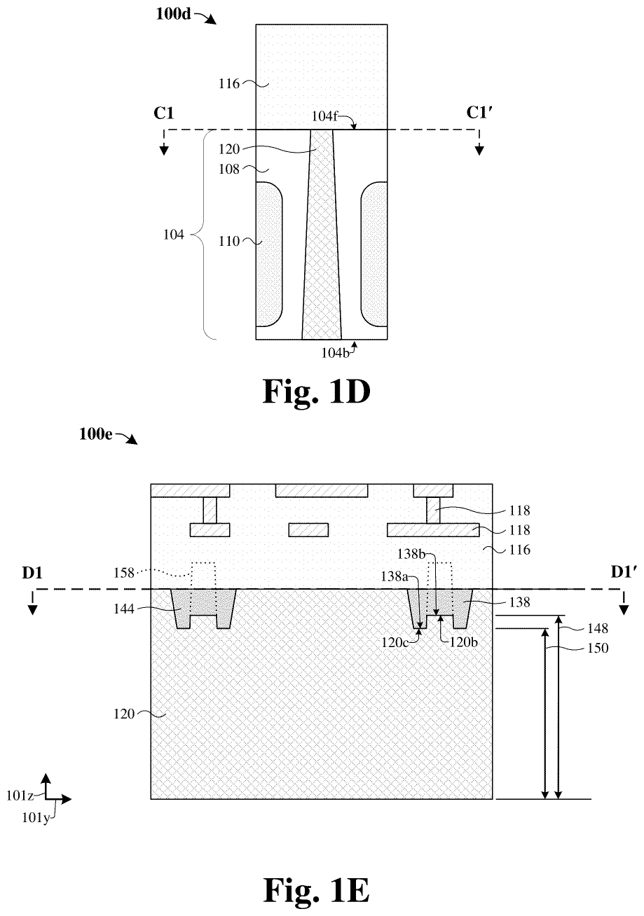

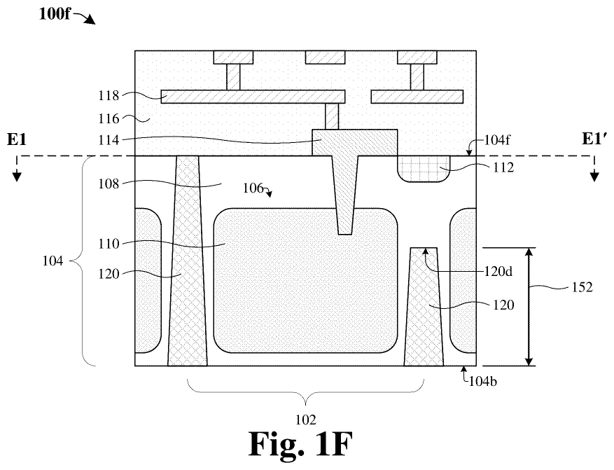

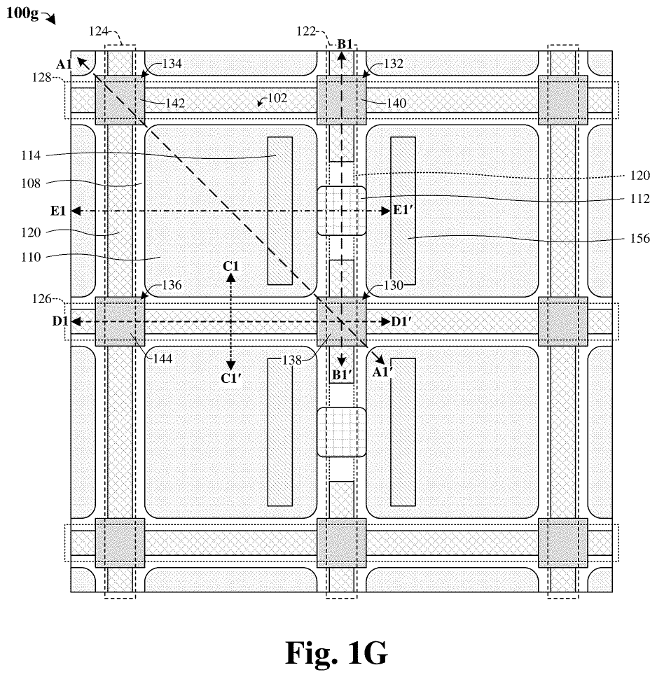

FIG. 1A, FIG. 1B, FIG. 1D, FIG. 1E, and FIG. 1F illustrate cross-sectional views 100a, 100b, 100d, 100e, 100f, respectively, of some embodiments of an image sensor including shallow trench isolation (STI) structures 138, 140, 142, 144 on a deep trench isolation (DTI) structure 120. FIG. 1C illustrates an enlarged cross-sectional view 100c of some embodiments of a portion of the image sensor of FIG. 1B. FIG. 1G illustrates a top view 100g of some embodiments of the image sensor of FIG. 1A, FIG. 1B, FIG. 1C, FIG. 1D, FIG. 1E, and FIG. 1F. In some embodiments, cross-sectional views 100a, 100b, 100d, 100e, 100f may, for example, be taken across line A1-A1′, line B1-B1′, line C1-C1′, line D1-D1′, and line E1-E1′, respectively, of FIG. 1G.

Referring to FIGS. 1A-1G, the image sensor includes a pixel 102 along a semiconductor substrate 104. The pixel 102 includes a photodetector 106 in the semiconductor substrate 104. For example, a bulk region 108 of the substrate 104 having a first doping type (e.g., p type or n type) and a photodetector region 110 of the substrate 104 having a second doping type (e.g., n type or p type), different than the first doping type, form the photodetector 106. A floating node 112 (e.g., a floating diffusion region) is in the substrate 104 and beside the photodetector 106. The floating node 112 has the second doping type. A transfer gate 114 is over and between the photodetector region 110 and the floating node 112. A dielectric structure 116 comprising one or more dielectric layers is over the substrate 104. A plurality of conductive interconnects 118 are within the dielectric structure 116. Some of the conductive interconnects 118 are coupled to the transfer gate 114 and some are coupled to the floating node 112.

A deep trench isolation (DTI) structure 120 extends into the substrate 104 (along direction 101z) from a backside 104b of the substrate 104 toward the frontside 104f and surrounds the photodetector 106. The DTI structure 120 comprises a first plurality of walls (e.g., a first wall 122 and a second wall 124) which are elongated along a first direction (e.g., direction 101y) and which are laterally spaced apart from one another. The DTI structure 120 comprises a second plurality of walls (e.g., a third wall 126 and a fourth wall 128) which are elongated along a second direction (e.g., direction 101x), transverse to the first direction, and which are laterally spaced apart from one another. The first plurality of walls and the second plurality of walls of the DTI structure 120 intersect at intersections. For example, the first wall 122 and the third wall 126 intersect at a first intersection 130, the first wall 122 and the fourth wall 128 intersect at a second intersection 132, the second wall 124 and the fourth wall 128 intersect at a third intersection 134, and the second wall 124 and the third wall 126 intersect at a fourth intersection 136.

Forming the DTI structure 120 comprises etching the substrate 104 from the backside 104b of the substrate 104 to form a trench in the substrate 104. The trench has a first plurality of “streets” and a second plurality of “streets”. An isolation material is deposited in the first streets of the trench to form the first walls of the DTI structure 120 in the first streets. The isolation material is deposited in the second streets of the trench to form the second walls of the DTI structure 120 in the second streets. In some cases, the depth of the etching is greater where the streets of the trench intersect (e.g., at intersections 130, 132, 134, 136) because the etching extends in two lateral directions (e.g., in both the first direction (along 101y) and the second direction (along 101x)) at these intersections. Consequently, in some cases, the etching may extend deeper than desired at these intersections. For example, in some cases, the etching may extend through the frontside 104f of the substrate 104 at these intersections, as illustrated by dashed lines 158 of FIG. 1A, FIG. 1B, and FIG. 1D. This over-etching may cause damage to the image sensor which may reduce a performance and/or reliability of the image sensor.

Thus, the image sensor includes shallow trench isolation (STI) structures (e.g., a first STI structure 138, a second STI structure 140, a third STI structure 142, and a fourth STI structure 144) at the intersections of the walls of the DTI structure 120 (e.g., at the first intersection 130, at the second intersection 132, at the third intersection 134, and at the fourth intersection 136, respectively) to block the etching from extending through the frontside 104f of the substrate 104 at the intersections. The STI structures 138, 140, 142, 144 extend into the substrate 104 (along direction 101z) from the frontside 104f of the substrate 104 toward the backside 104b directly over the DTI structure 120 at the intersections of the walls of the DTI structure 120. The etch rate of the STI structures 138, 140, 142, 144 is substantially less than the etch rate of the substrate 104. Thus, the STI structures 138, 140, 142, 144 slow the etching at the intersections. For example, the etching (and thus the DTI structure 120) extends into bottoms of the STI structures 138, 140, 142, 144 but not through tops of the STI structures 138, 140, 142, 144. Because the STI structures 138, 140, 142, 144 slow the etching at the intersections 130, 132, 134, 136, a likelihood of over-etching (and hence damage) at the intersections can be reduced. Further, by including the STI structures over the intersections but not over the full lengths of the walls of the DTI structure 120, electrical noise may be reduced.

Along the walls of the DTI structure 120 (between the intersections), the DTI structure 120 extends from the backside 104b of the substrate 104 to a first depth 146 from the backside 104b of the substrate 104. For example, along the first wall 122 (between the first intersection 130 and the second intersection 132), the DTI structure 120 has a first upper surface 120a at the first depth 146 from the backside 104b of the substrate 104. The first depth is approximately equal to the thickness of the substrate 104 so that the first upper surface 120a of the DTI structure 120 extends along (e.g., is approximately level with) the frontside 104f of the substrate 104. The DTI structure 120 isolates the pixel 102 from neighboring pixels along the walls of the DTI structure 120.

At the intersections of the walls of the DTI structure 120, the DTI structure 120 extends from the backside 104b of the substrate 104 to a second depth 148 from the backside 104b of the substrate 104. For example, at the first intersection 130, the DTI structure 120 has a second upper surface 120b at the second depth 148 from the backside 104b of the substrate 104. The second depth 148 is less than the first depth 146. Further, at the intersections, the STI structures extend from the frontside 104f of the substrate 104 to a third depth 150 from the backside 104b of the substrate 104. For example, at the first intersection 130, the first STI structure 138 has a first lower surface 138a at the third depth 150 from the backside 104b of the substrate 104. Further, the first STI structure 138 has a second lower surface 138b on the second upper surface 120b of the DTI structure 120 (e.g., at the second depth 148). The third depth 150 is less than the second depth 148 so that lower portions of the STI structures 138, 140, 142, 144 vertically overlap with upper portions of the DTI structure 120. Together the DTI structure 120 and the STI structures 138, 140, 142, 144 isolate the pixel 102 from neighboring pixels at the intersections.

The first lower surface 138a of the first STI structure 138 is on a third upper surface 120c of the DTI structure 120. The DTI structure 120 has a first sidewall 120e that extends along an inner sidewall 138c of the first STI structure 138 from the third upper surface 120c to the second upper surface 120b. The DTI structure 120 has a second sidewall 120f that extends along an outer sidewall 138d of the first STI structure 138 from the third upper surface 120c to the first upper surface 120a.

The DTI structure 120 has a fourth upper surface 120d spaced directly under the floating node 112. The fourth upper surface 120d is at a fourth depth 152 from the backside 104b of the substrate 104. The fourth depth 152 is less than the third depth 150. The fourth upper surface 120d extends laterally beyond sides of the floating node 112. The DTI structure 120 has a third sidewall 120g that extends along the substrate 104 from the fourth upper surface 120d to the first upper surface 120a.

The floating node 112 is directly over a wall of the DTI structure 120 (e.g., the first wall 122). The floating node 112 is between the transfer gate 114 and a transfer gate 156 of a neighboring pixel (not labeled) so that the two transfer gates 114, 156 control current through the floating node 112.

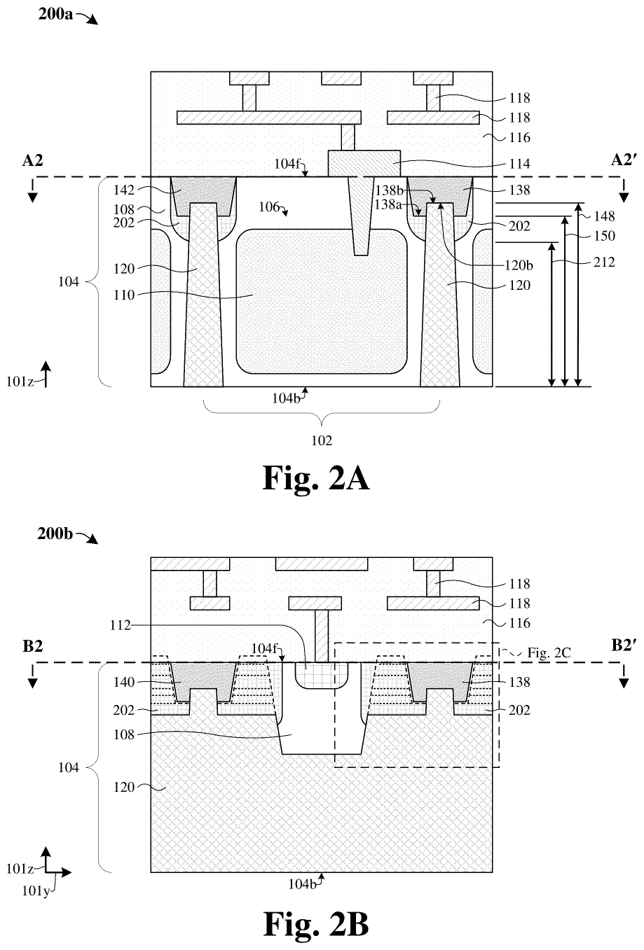

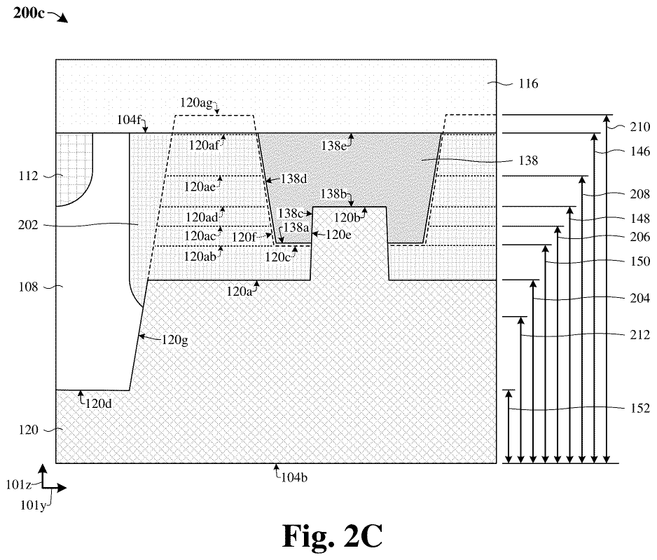

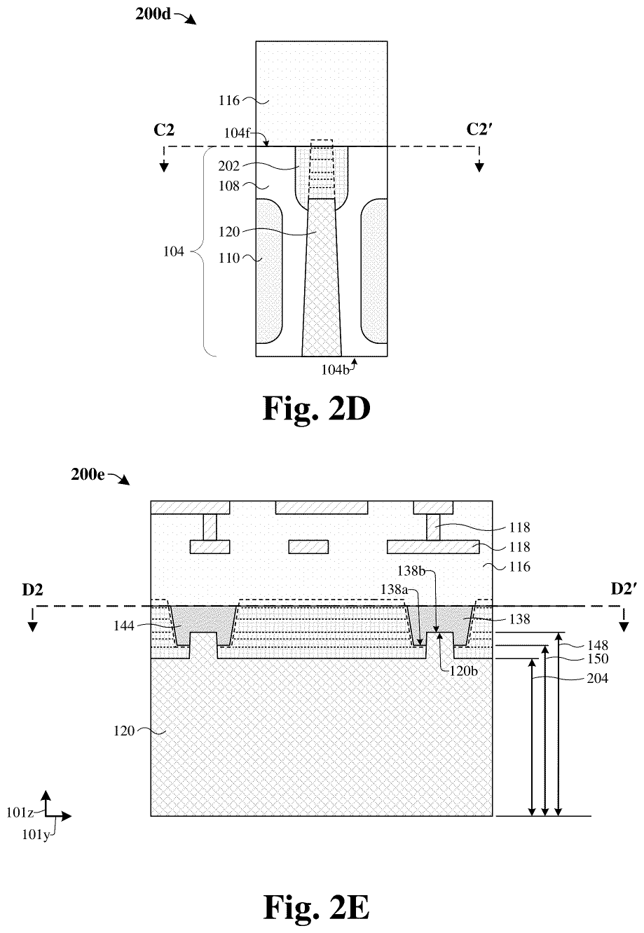

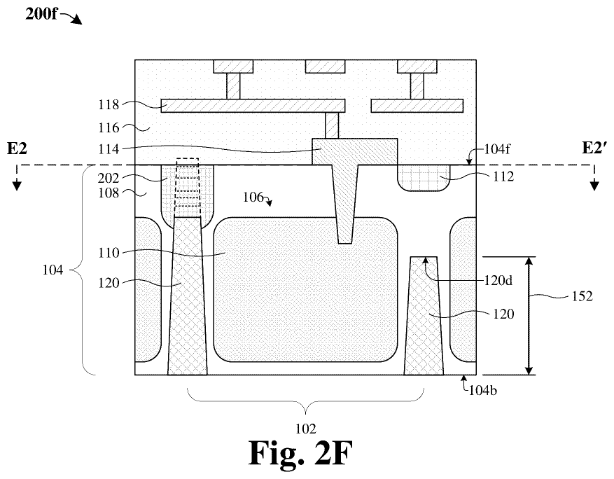

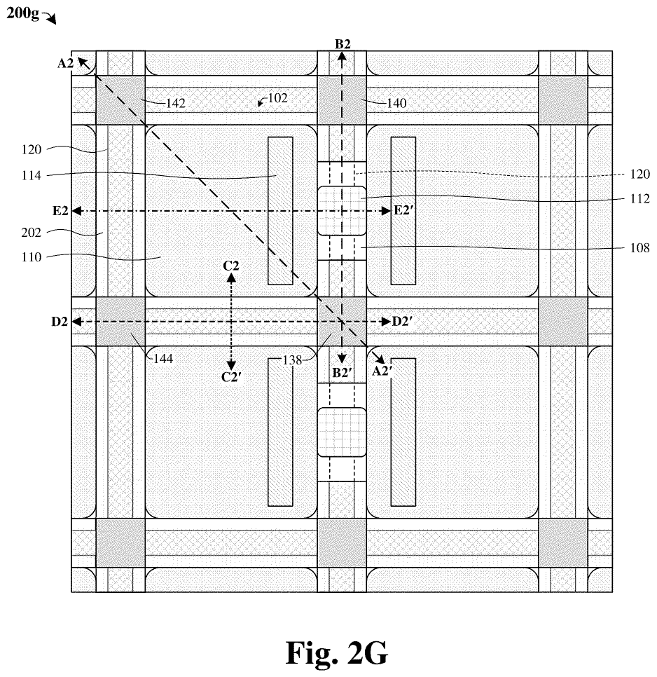

FIG. 2A, FIG. 2B, FIG. 2D, FIG. 2E, and FIG. 2F illustrate cross-sectional views 200a, 200b, 200d, 200e, 200f, respectively, of some embodiments of the image sensor of FIGS. 1A-1G in which the substrate 104 includes an isolation region 202 along the frontside 104f of the substrate 104. FIG. 2C illustrates an enlarged cross-sectional view 200c of some embodiments of a portion of the image sensor of FIG. 2B. FIG. 2G illustrates a top view 200g of some embodiments of the image sensor of FIG. 2A, FIG. 2B, FIG. 2C, FIG. 2D, FIG. 2E, and FIG. 2F. In some embodiments, cross-sectional views 200a, 200b, 200d, 200e, 200f may, for example, be taken across line A2-A2′, line B2-B2′, line D2-D2′, line E2-2E2′, and line F2-F2′, respectively, of FIG. 2G.

The isolation region 202 extends from the frontside 104f toward the backside 104b of the substrate 104. The isolation region 202 is a doped region of the substrate having the first doping type.

In some embodiments, along the walls of the DTI structure 120, the DTI structure 120 is below bottom surfaces of the STI structures 138, 140, 142, 144. For example, the first upper surface 120a of the DTI structure 120 is at a depth 204 from the backside 104b which is less than depth 150 so that the first upper surface 120a of the DTI structure 120 is spaced below the first lower surface 138a of the first STI structure 138. The first sidewall 120e of the DTI structure 120 extends along the inner sidewall 138c of the first STI structure 138 from the first upper surface 120a to the second upper surface 120b. The substrate 104 (e.g., the isolation region 202 of the substrate 104) is directly between the first lower surface 138a of the first STI structure 138 and the first upper surface 120a of the DTI structure 120.

The isolation region 202 is directly over the DTI structure 120 and extends along sidewalls of the DTI structure 120. The isolation region is also on sidewalls and lower surfaces of the STI structures (e.g., the outer sidewall 138d and the first lower surface 138a of the first STI structure 138). The isolation region 202 is shown as partially transparent in FIG. 2G (and various other figures) so that the underlying DTI structure 120 can be seen.

The isolation region 202 extends into the substrate to a depth 212 from the backside 104b. Depth 212 is less than depth 204 so that there is a vertical overlap between a bottom portion of the isolation region 202 and a top portion of the DTI structure 120 along the walls of the DTI structure 120. Thus, the DTI structure 120 and the isolation region 202 together isolate the pixel 102 from neighboring pixels along the sides of the pixel 102 (e.g., along the walls of the DTI structure 120). In some embodiments, depth 204 is greater than 2.5 micrometers, greater than 2.7 micrometers, or some other suitable value.

Although FIG. 2C shows the first upper surface 120a spaced below the first lower surface 138a of the first STI structure 138, in some other embodiments, the first lower surface (e.g., as illustrated by dashed line 120ab) of the DTI structure 120 is extends along the first lower surface 138a of the first STI structure 138. For example, the first upper surface (e.g., 120ab) of the DTI structure 120 is approximately at depth 150 so that the first lower surface 138a of the first STI structure 138 is on the first upper surface (e.g., 120ab) of the DTI structure 120. The first sidewall 120e of the DTI structure 120 extends along the inner sidewall 138c of the first STI structure 138 from the first upper surface (e.g., 120ab) to the second upper surface 120b.

In some other embodiments, the first upper surface (e.g., illustrated by dashed line 120ac) of the DTI structure 120 is above the first lower surface 138a of the first STI structure 138. For example, the first upper surface (e.g., 120ac) of the DTI structure 120 is at a depth 206 from the backside 104b which is greater than depth 150 and less than depth 148 so that the first upper surface (e.g., 120ac) is above the first lower surface 138a of the first STI structure 138 and below the second upper surface 120b. In such embodiments, the DTI structure 120 has the third upper surface 120c extending along the first lower surface 138a of the first STI structure 138. A second sidewall (e.g., illustrated by dashed line 120f) of the DTI structure 120 extends along the outer sidewall 138d of the first STI structure 138 from the third upper surface 120c to the first upper surface (e.g., 120ac).

In some other embodiments, the first upper surface (e.g., illustrated by dashed line 120ad) of the DTI structure 120 is at a similar depth as second upper surface 120b of the DTI structure 120. For example, the first upper surface (e.g., 120ad) of the DTI structure 120 is approximately at depth 148 so that the first upper surface (e.g., 120ad) is approximately level with the second upper surface 120b.

In some other embodiments, the first upper surface (e.g., illustrated by dashed line 120ae) of the DTI structure 120 is above the second upper surface 120b of the DTI structure 120. For example, the first upper surface (e.g., 120ae) of the DTI structure 120 is at a depth 208 from the backside 104b which is greater than depth 148 and less than the thickness of the substrate so that the first upper surface (e.g., 120ae) is above the second upper surface 120b and below the frontside 104f of the substrate 104.

In some other embodiments, the first upper surface (e.g., illustrated by dashed line 120af) of the DTI structure 120 is at the frontside 104f of the substrate 104. For example, the first upper surface (e.g., 120af) of the DTI structure 120 is at depth 146 from the backside 104b which is approximately equal to the thickness of the substrate 104 so that the first upper surface (e.g., 120af) is approximately level with the frontside 104f of the substrate 104. The DTI structure 120 covers the sidewall 138c of the first STI structure 138 from the first lower surface 138a to the top surface 138e of the first STI structure 138. In some embodiments, depth 146 (and the thickness of the substrate 104) ranges from 2.8 micrometers to 3.2 micrometers, from 2.9 micrometers to 3.1 micrometers, or some other suitable value.

In some other embodiments, the first upper surface (e.g., illustrated by dashed line 120ag) of the DTI structure 120 is above the frontside 104f of the substrate 104. For example, the first upper surface (e.g., 120ag) of the DTI structure 120 is at a depth 210 from the backside 104b which is greater than the thickness of the substrate 104 so that the first upper surface (e.g., 120ag) is above the frontside 104f of the substrate 104.

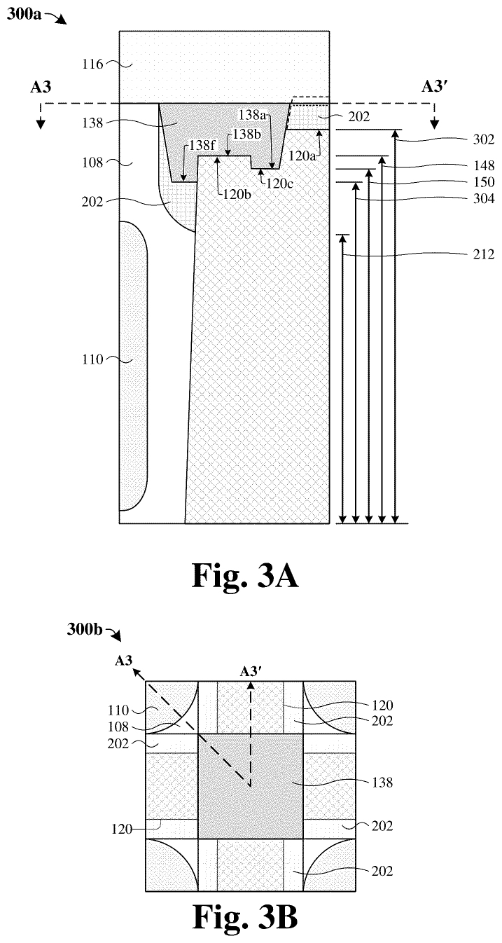

FIG. 3A illustrates a cross-sectional view 300a of some embodiments of the image sensor of FIGS. 2A-2G in which the first STI structure 138 has three lower surfaces at three different depths from the backside 104b of the substrate 104. FIG. 3B illustrates a top view 300b of some embodiments of the image sensor of FIG. 3A. In some embodiments, cross-sectional view 300a may, for example, be taken across line A3-A3′ of FIG. 3B.

The first upper surface 120a of the DTI structure 120 is at a depth 302 from the backside 104b. Depth 302 is greater than the second depth 148 so that the first upper surface 120a is above the second upper surface 120b of the DTI structure 120. The first STI structure 138 has a third lower surface 138f at a depth 304 from the backside 104b. Depth 304 is less than the third depth 150 so that the third lower surface 138f is below the first lower surface 138a of the first STI structure 138.

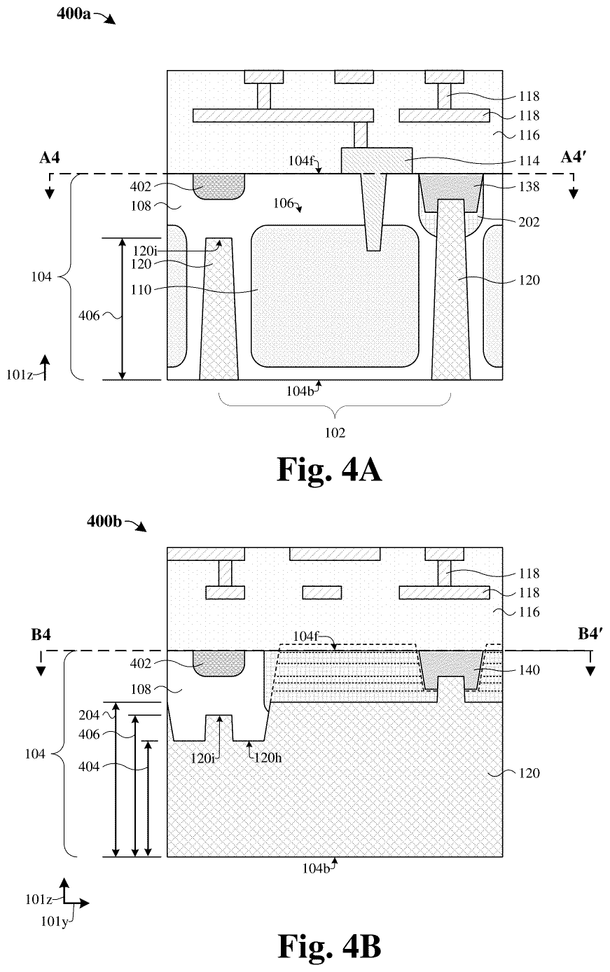

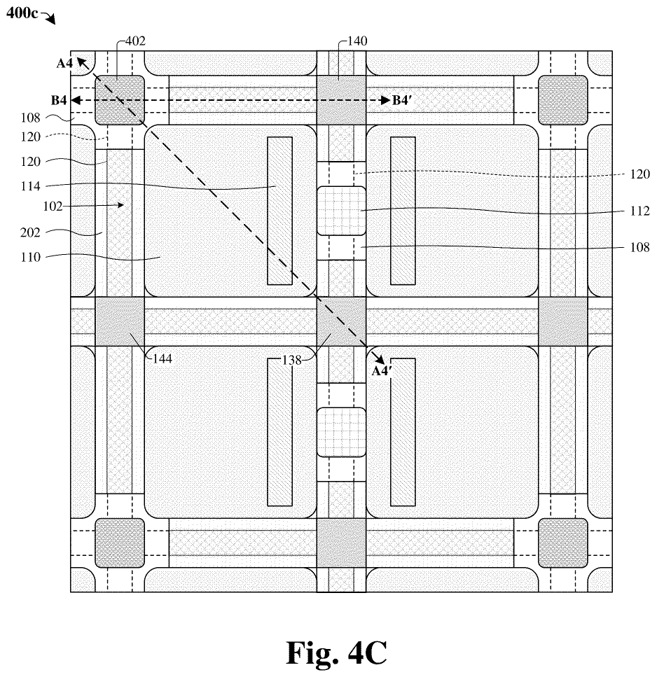

FIG. 4A and FIG. 4B illustrate cross-sectional views 400a, 400b, respectively of some embodiments of the image sensor of FIGS. 2A-2G in which the substrate 104 includes a pickup region 402 along the frontside 104f of the substrate 104. FIG. 4C illustrates a top view 400c of some embodiments of the image sensor of FIG. 4A and FIG. 4B. In some embodiments, cross-sectional views 400a, 400b may, for example, be taken across line A4-A4′ and line B4-B4′, respectively, of FIG. 4C.

The pickup region 402 extends from the frontside 104f toward the backside 104b of the substrate 104. The pickup region 402 is a doped region of the substrate 104 having the first doping type. The pickup region 402 is disposed at an intersection where walls of the DTI structure 120 intersect. The DTI structure 120 is vertically spaced from the pickup region 402. For example, the DTI structure 120 has an upper surface 120h spaced directly under the pickup region 402. Upper surface 120h is at a depth 404 from the backside 104b of the substrate 104. Depth 404 is less than depth 204. The DTI structure 120 has a protrusion at the intersection and thus directly under the pickup region 402. The protrusion protrudes upward toward the pickup region 402 and is formed by an upper surface 120i above upper surface 120h. Upper surface 120i is at a depth 406 from the backside 104b. Depth 406 is greater than depth 404 and less than depth 204. In some embodiments, depth 404 is approximately equal to depth 152.

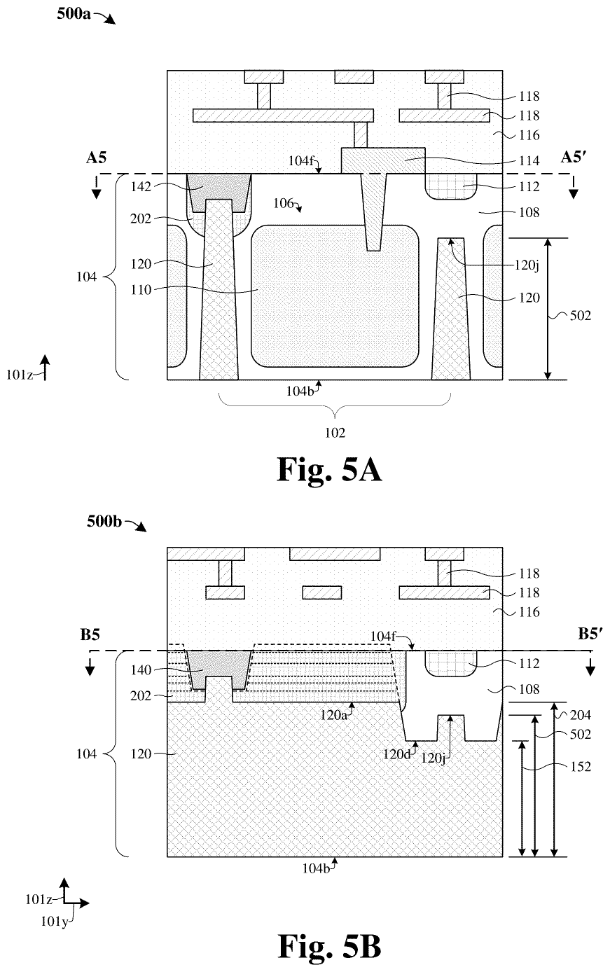

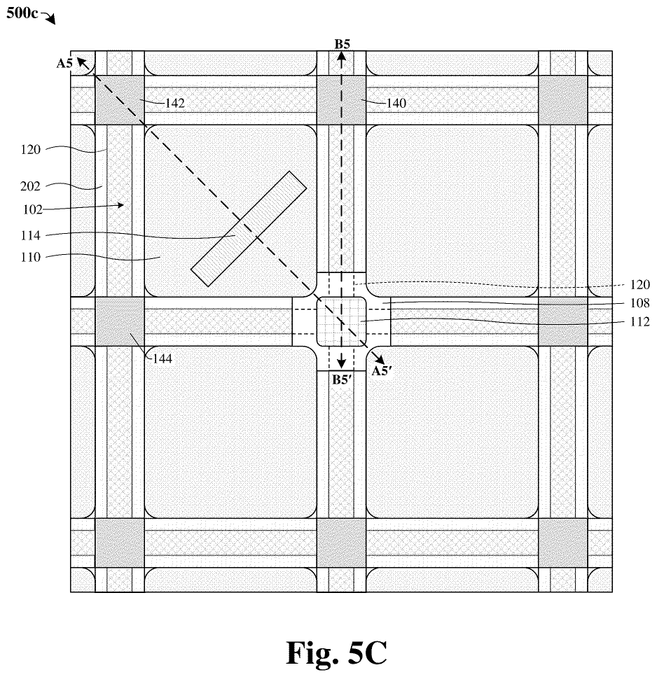

FIG. 5A and FIG. 5B illustrate cross-sectional views 500a, 500b, respectively of some embodiments of the image sensor of FIGS. 2A-2G in which the floating node 112 is disposed at an intersection where one wall of the DTI structure 120 intersects with another wall of the DTI structure 120. FIG. 5C illustrates a top view 500c of some embodiments of the image sensor of FIG. 5A and FIG. 5B. In some embodiments, cross-sectional views 500a, 500b may, for example, be taken across line A5-A5′ and line B5-B5′, respectively, of FIG. 5C.

The DTI structure 120 is vertically spaced from the floating node 112. For example, the DTI structure 120 has the fourth upper surface 120d spaced directly under the floating node 112. The DTI structure 120 has a protrusion at the intersection (e.g., the first intersection 130) and thus directly under the floating node 112. The protrusion protrudes upward toward the floating node 112 and is formed by an upper surface 120j above the fourth upper surface 120d. Upper surface 120j is at a depth 502 from the backside 104b. Depth 502 is greater than depth 152 and less than depth 204.

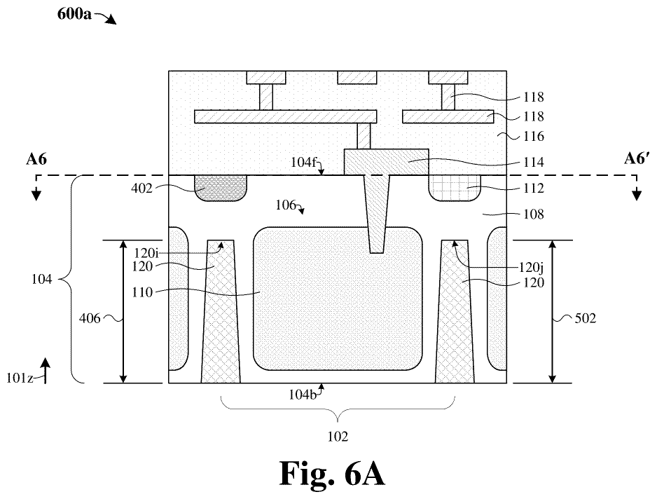

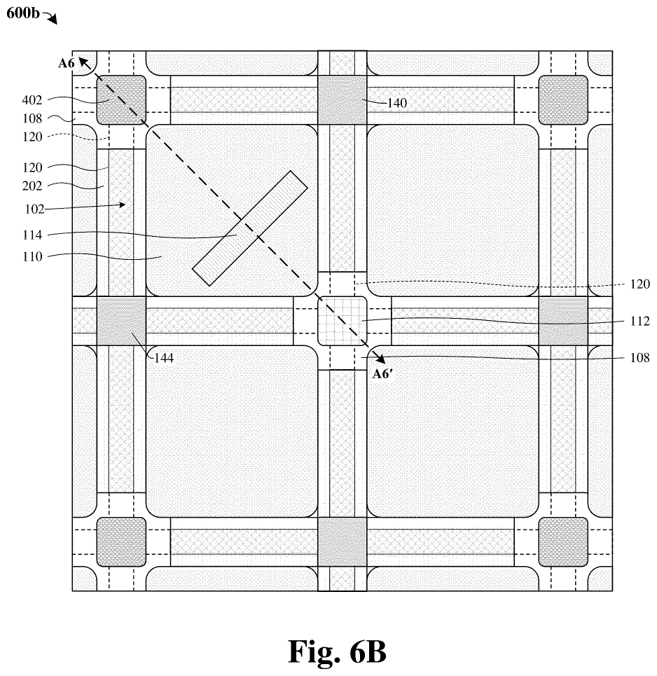

FIG. 6A illustrates a cross-sectional view 600a of some embodiments of the image sensor of FIGS. 2A-2G in which both the floating node 112 and the pickup region 402 are disposed at intersections of the walls of the DTI structure 120. FIG. 6B illustrates a top view 600b of some embodiments of the image sensor of FIG. 6A. In some embodiments, cross-sectional view 600a may, for example, be taken across line A6-A6′ of FIG. 6B.

In some embodiments, the pickup region 402 and the floating node 112 are disposed at opposite (e.g., diagonal) intersections of walls of the DTI structure 120. In some embodiments, depth 502 is approximately equal to depth 406.

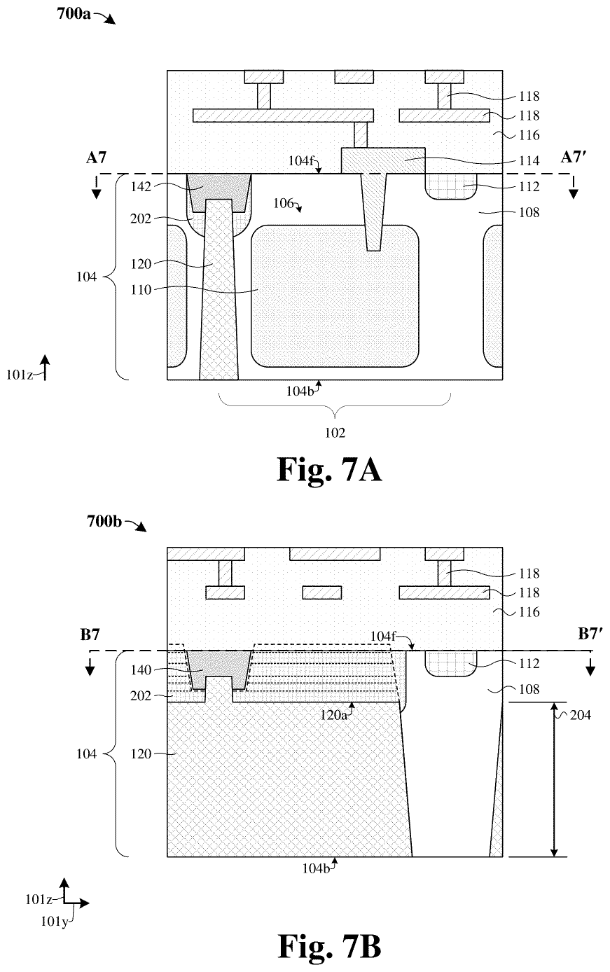

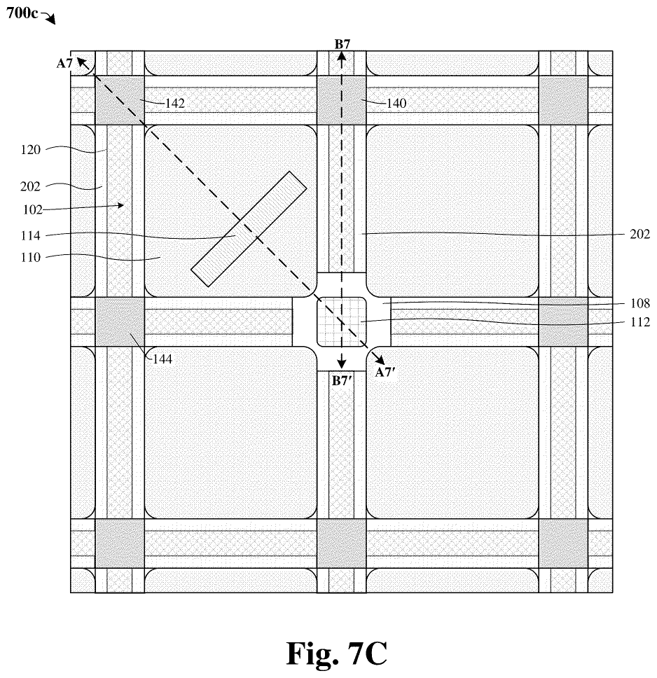

FIG. 7A and FIG. 7B illustrate cross-sectional views 700a, 700b, respectively of some embodiments of the image sensor of FIGS. 2A-2G in which the DTI structure 120 is laterally spaced from the floating node 112. FIG. 7C illustrates a top view 700c of some embodiments of the image sensor of FIG. 7A and FIG. 7B. In some embodiments, cross-sectional views 700a, 700b may, for example, be taken across line A7-A7′ and line B7-B7′, respectively, of FIG. 7C.

The DTI structure 120 does not extend directly under the floating node 112. Instead, the bulk region 108 of the substrate 104 extends from a bottom of the floating node 112 to the backside 104b of the substrate 104. Sidewalls (not labeled) of the DTI structure 120 are laterally spaced from sides of the floating node 112.

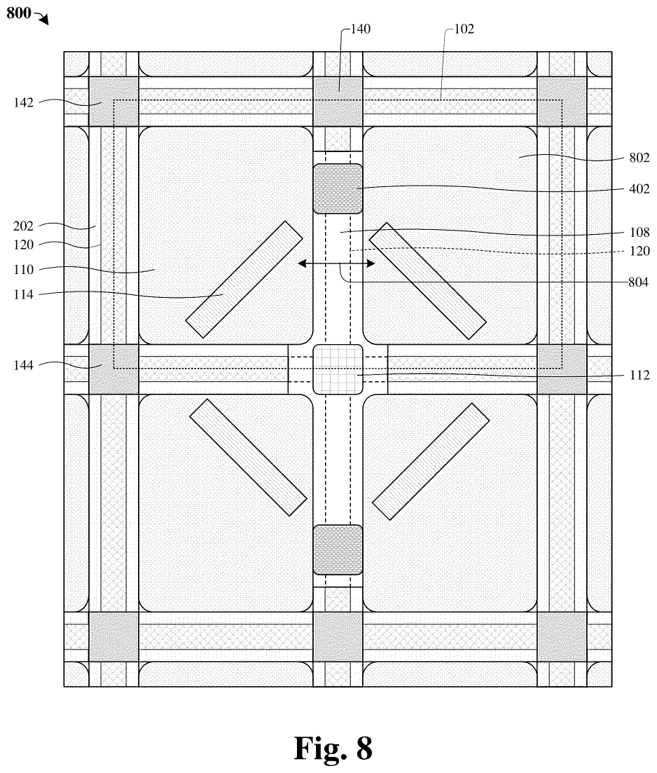

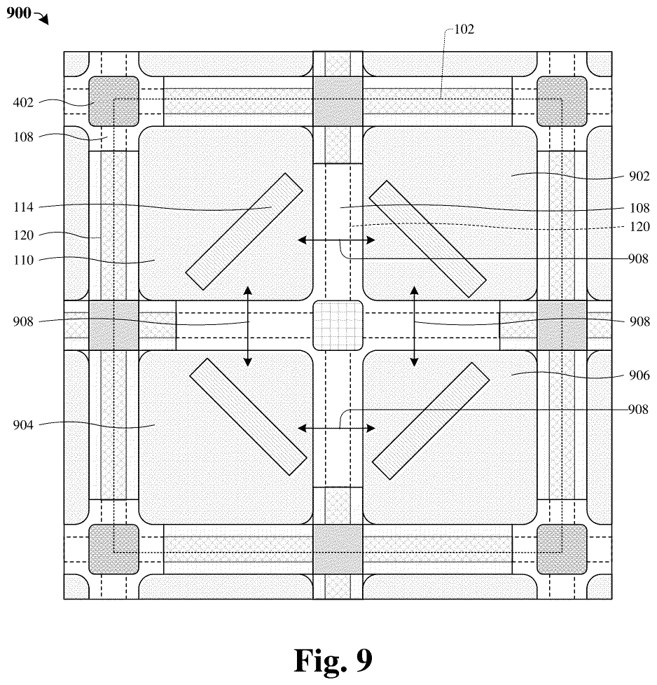

FIG. 8 and FIG. 9 illustrate top views 800, 900, respectively, of some embodiments of the image sensor of FIGS. 2A-2G in which the pixel 102 includes more than one photodetector region.

In some embodiments (e.g., as shown in FIG. 8), the pixel 102 includes two photodetector regions. The bulk region 108 extends from a side of one photodetector region 110 to the side of the other photodetector region 802 along an inter-pixel overflow path (e.g., illustrated by line 804). In some embodiments, a pickup region 402 is directly between the photodetector regions 110, 802.

In some other embodiments (e.g., as shown in FIG. 9), the pixel 102 includes four photodetector regions. The bulk region 108 extends between the four photodetector regions 110, 902, 904, 906 along inter-pixel paths (e.g., illustrated by lines 908).

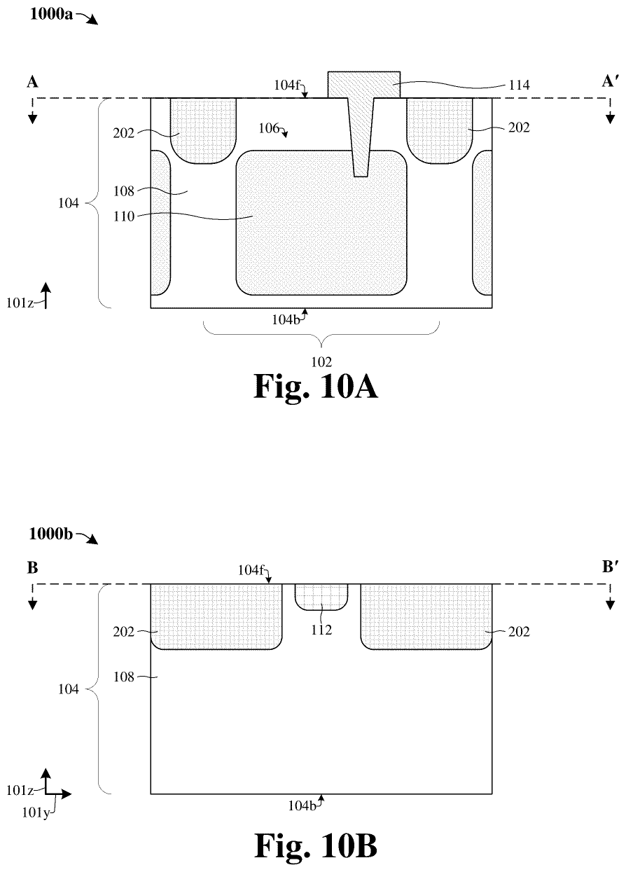

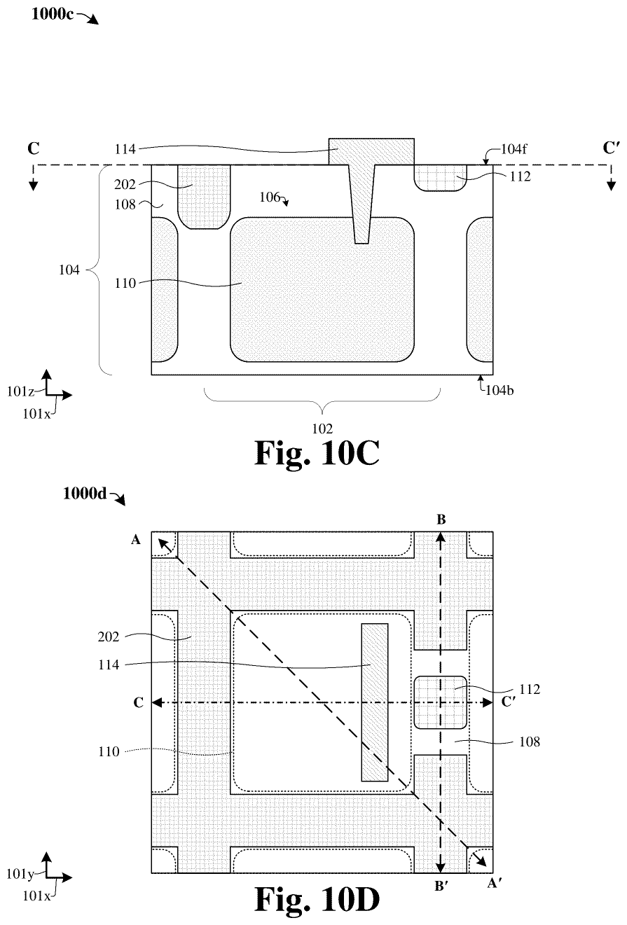

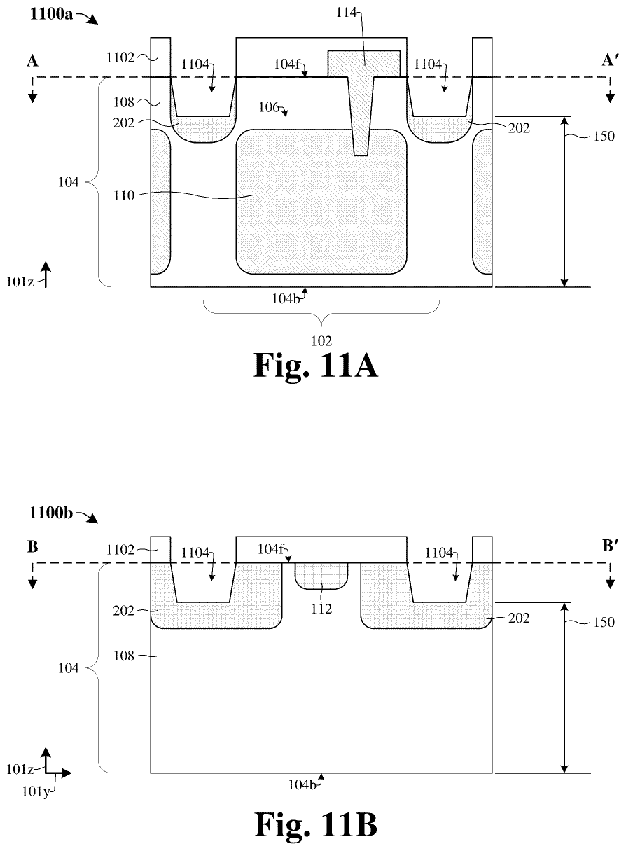

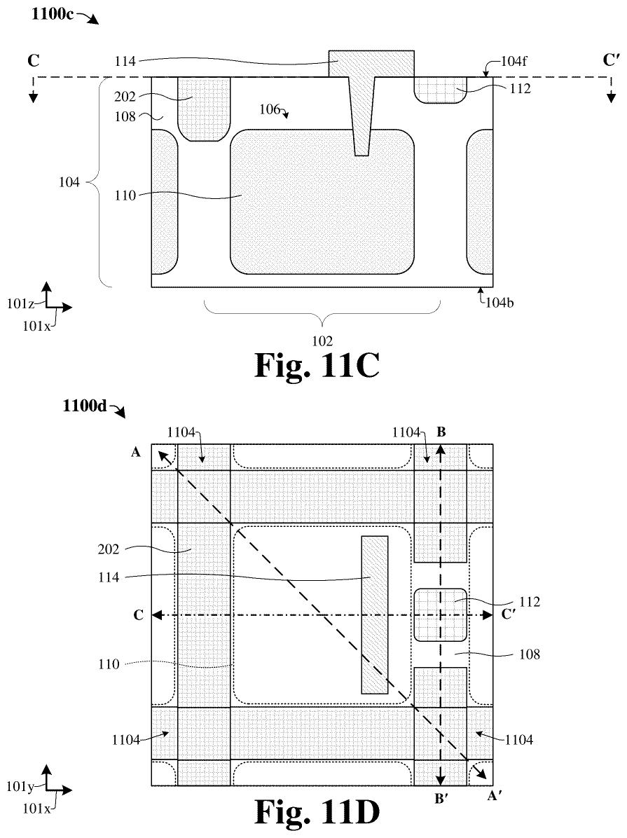

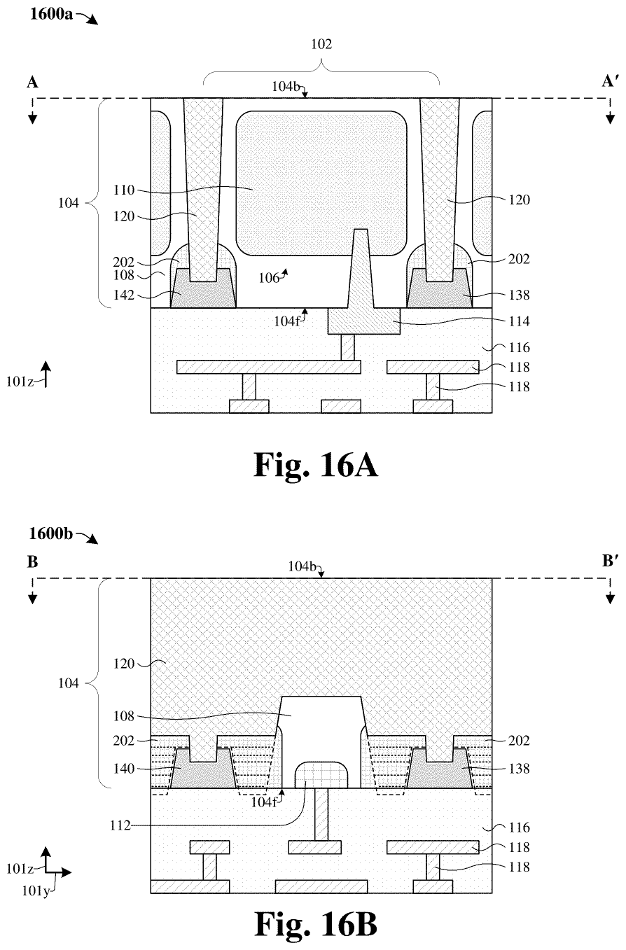

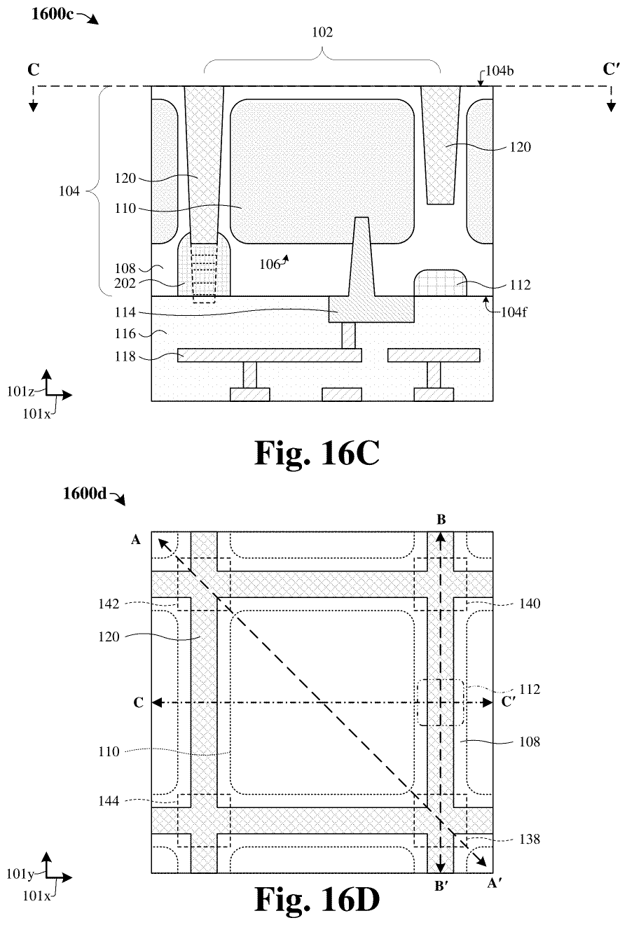

FIGS. 10A, 10B, 10C, 10D through FIGS. 16A, 16B, 16C, 16D illustrate various views of some embodiments of a method for forming an image sensor including STI structures 138, 140, 142, 144 on a DTI structure 120. Although FIGS. 10A, 10B, 10C, 10D through FIGS. 16A, 16B, 16C, 16D are described in relation to a method, it will be appreciated that the structures disclosed in FIGS. 10A, 10B, 10C, 10D through FIGS. 16A, 16B, 16C, 16D are not limited to such a method, but instead may stand alone as structures independent of the method. In some embodiments, cross-sectional views 1000a, 1000b, 1000c may, for example, be taken across line A-A′, line B-B′, and line C-C′, respectively, of FIG. 10D, cross-sectional views 1100a, 1100b, 1100c may, for example, be taken across line A-A′, line B-B′, and line C-C′, respectively, of FIG. 11D, and so on through FIGS. 16A, 16B, 16C, 16D.

As shown in cross-sectional views 1000a, 1000b, 1000c, and top view 1000d of FIGS. 10A, 10B, 10C, 10D, respectively, a pixel 102 including photodetector 106 is formed along a substrate 104. For example, a photodetector region 110 is formed in the substrate 104 and a bulk region 108 of the substrate 104 surrounds the photodetector region 110. The bulk region 108 has a first doping type and the photodetector region 110 has a second doping type different than the first doping type. A transfer gate 114 is formed over the substrate 104.

In some embodiments, the transfer gate 114 extends into the photodetector region 110 from the frontside 104f toward the backside 104b. A floating node 112 (e.g., a floating diffusion region) is formed in the substrate 104 along a frontside 104f of the substrate 104. The floating node 112 has the second doping type.

In some embodiments, an isolation region 202 having the first doping type is formed in the substrate 104 along the frontside 104f of the substrate. The isolation region 202 at least partially surrounds the photodetector region 110 along the frontside 104f of the substrate 104.

In some embodiments, a pickup region (e.g., pickup region 402 of FIGS. 4A-4C) having the first doping type is formed in the substrate 104 along the frontside 104f.

In some embodiments, the various doped regions are formed in the substrate 104 by ion implantation processes or some other suitable processes. In some embodiments, the transfer gate 114 is formed over and in the substrate 104 by etching the substrate 104, depositing a gate electrode material over the substrate, and etching the gate electrode material.

As shown in cross-sectional views 1100a, 1100b, 1100c, and top view 1100d of FIGS. 11A, 11B, 11C, 11D, respectively, the frontside 104f of the substrate 104 is etched to form openings 1104 in the substrate 104 at corners of the pixel 102. The etching extends into the isolation region 202 to a depth 150 from the backside 104b of the substrate 104. In some embodiments, a masking layer 1102 is formed over the substrate 104 and the etching is performed according to openings in the masking layer 1102. In some embodiments, the masking layer 1102 comprises photoresist, a hard mask material, or some other suitable material. In some embodiments, the etching comprises a dry etching process (e.g., a plasma etching process, a reactive ion etching process, an ion beam etching process, or the like) or some other suitable process.

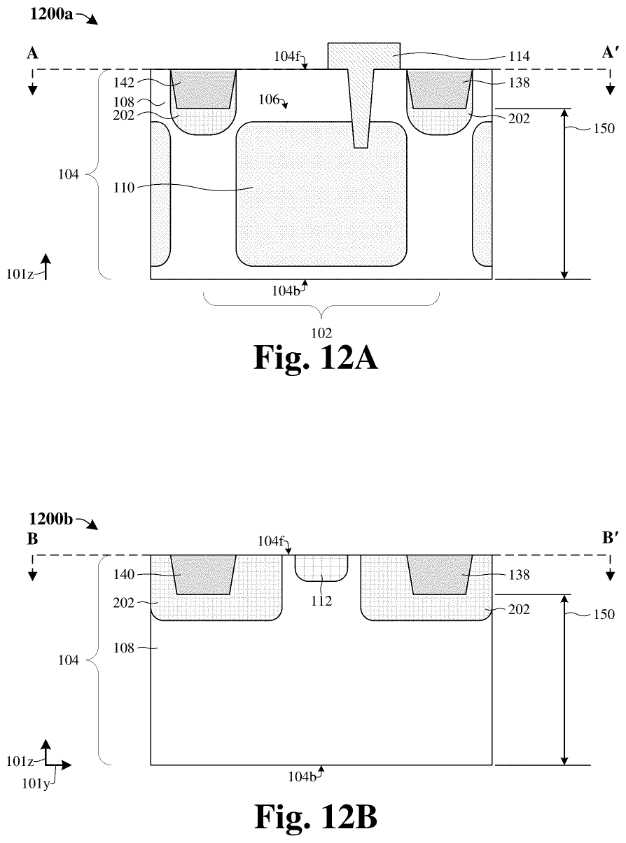

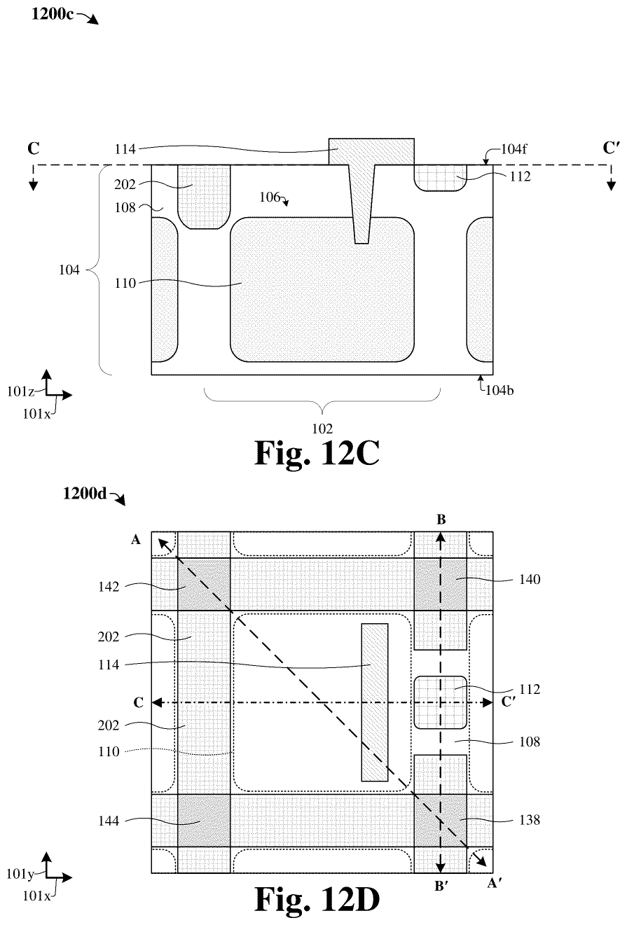

As shown in cross-sectional views 1200a, 1200b, 1200c, and top view 1200d of FIGS. 12A, 12B, 12C, 12D, respectively, STI structures 138, 140, 142, 144 are formed in the openings 1104. The STI structures 138, 140, 142, 144 are formed by depositing a first dielectric over the frontside 104f and in the openings 1104 and subsequently performing a polishing or planarization process (e.g., a chemical mechanical polishing/planarization (CMP) process, a blanket etch-back process, or some other suitable process) on the first dielectric to remove the first dielectric from over the frontside 104f and delimit the STI structures 138, 140, 142, 144. In some embodiments, the first dielectric comprises silicon dioxide, aluminum oxide, or some other suitable material and is deposited by a chemical vapor deposition (CVD) process, a physical vapor deposition (PVD) process, an atomic layer deposition (ALD) process, or some other suitable process.

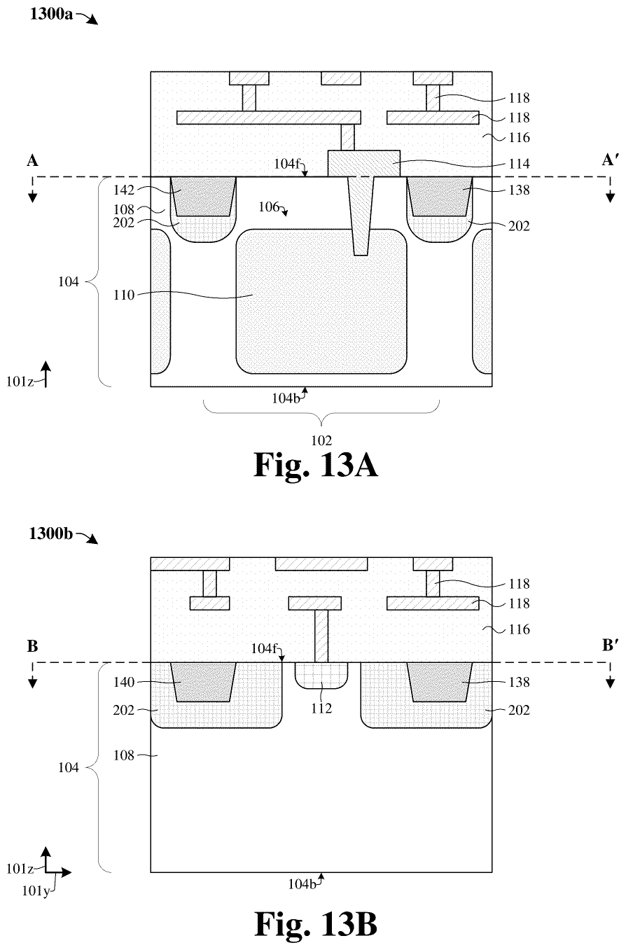

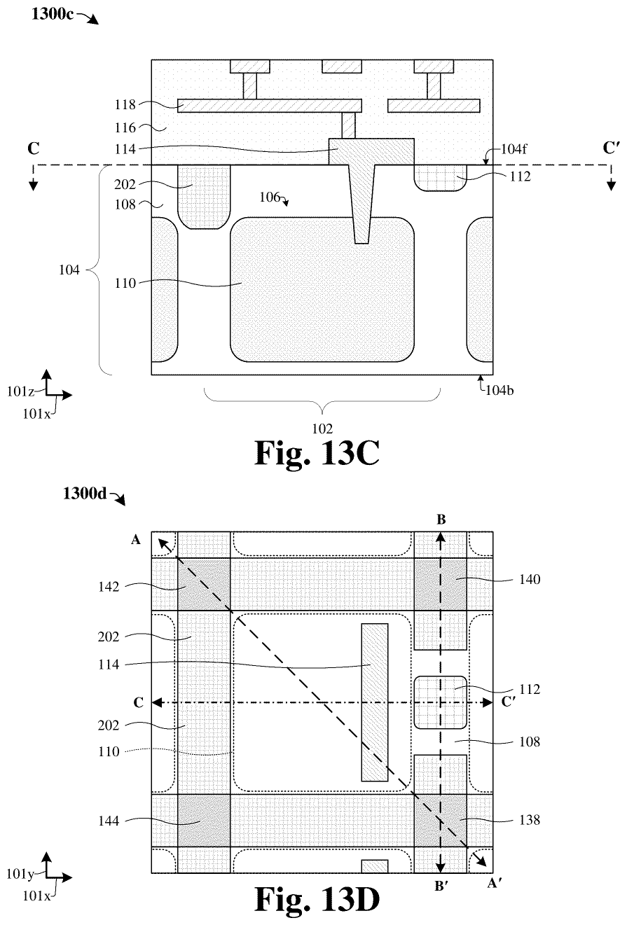

As shown in cross-sectional views 1300a, 1300b, 1300c, and top view 1300d of FIGS. 13A, 13B, 13C, 13D, respectively, a dielectric structure 116 comprising one or more dielectric layers is formed over the substrate 104 and a plurality of conductive interconnects 118 are formed within the dielectric structure 116. In some embodiments, the dielectric structure 116 is formed by depositing a plurality of dielectric layers over the frontside 104f of the substrate 104. In some embodiments, the dielectric layers of the dielectric structure 116 comprise silicon dioxide, silicon nitride, silicon carbide or some other suitable material and are deposited by a CVD process, a PVD process, an ALD process, or some other suitable process. In some embodiments, the conductive interconnects 118 are formed by etching the dielectric layers of the dielectric structure 116 and depositing conductive materials over the etched dielectric layers. In some embodiments, the conductive interconnects comprise copper, aluminum, tungsten, or some other suitable material and are deposited by a CVD process, a PVD process, an ALD process, or some other suitable process.

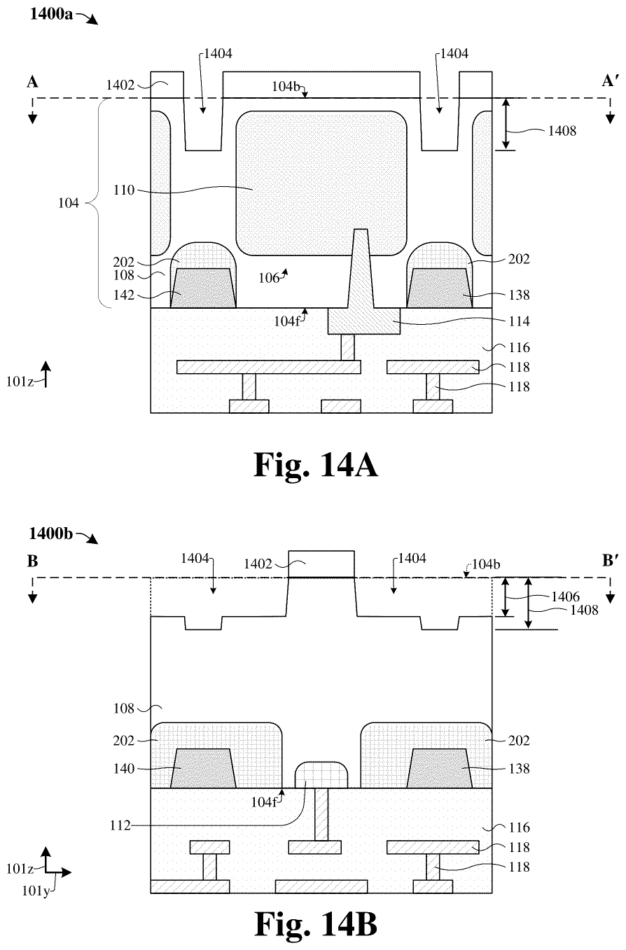

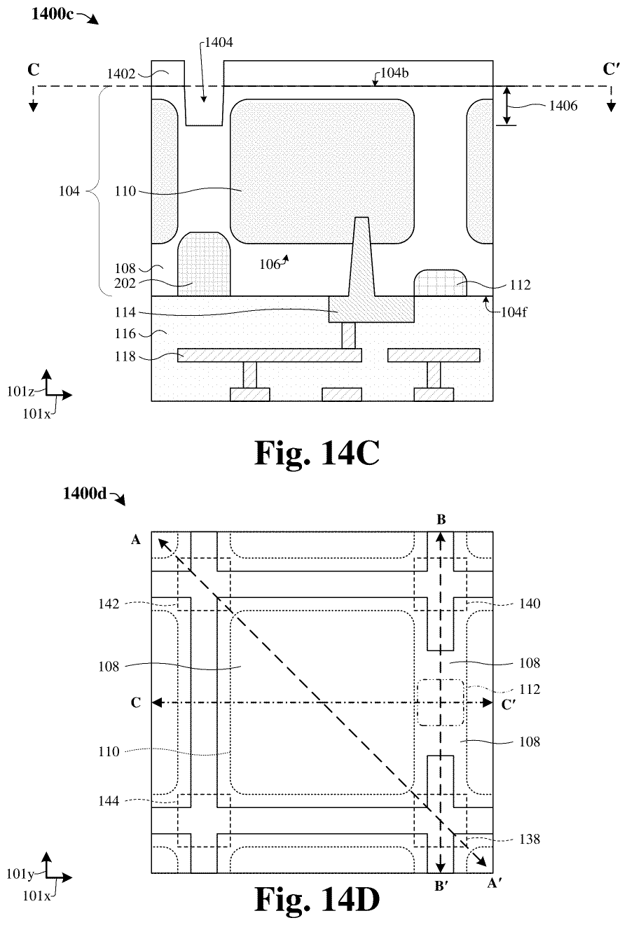

As shown in cross-sectional views 1400a, 1400b, 1400c, and top view 1400d of FIGS. 14A, 14B, 14C, 14D, respectively, the backside 104b of the substrate 104 is etched. The etching extends vertically into the substrate 104 (e.g., along direction 101z). The etching extends laterally along a first direction (e.g., along direction 101y) to form first “streets” of a trench 1404. The etching further extends laterally along a second direction (e.g., along direction 101x), transverse to the first direction, to form second “streets” of the trench 1404 in the substrate 104. The etching extends to depth 1406 from the backside 104b along sides of the pixel 102 (e.g., along the streets of the trench 1404) and to depth 1408 along corners of the pixel 102 (e.g., along intersections of the streets of the trench 1404).

In some embodiments, a masking layer 1402 is formed over the substrate 104 and the etching is performed according to openings in the masking layer 1402. In some embodiments, the masking layer 1402 comprises photoresist, a hard mask material, or some other suitable material. In some embodiments, the masking layer 1402 is directly over the floating node 112 during the etching so the substrate 104 is not etched directly over the floating node 112. In some embodiments, the etching comprises a dry etching process or some other suitable process.

The depth of the trench 1404 is greater at the intersections of the streets of the trench 1404 because the etching is performed along two lateral directions (e.g., along 101y and along 101x) at these intersections versus one lateral direction along the streets (e.g., along 101y or along 101x depending on the street).

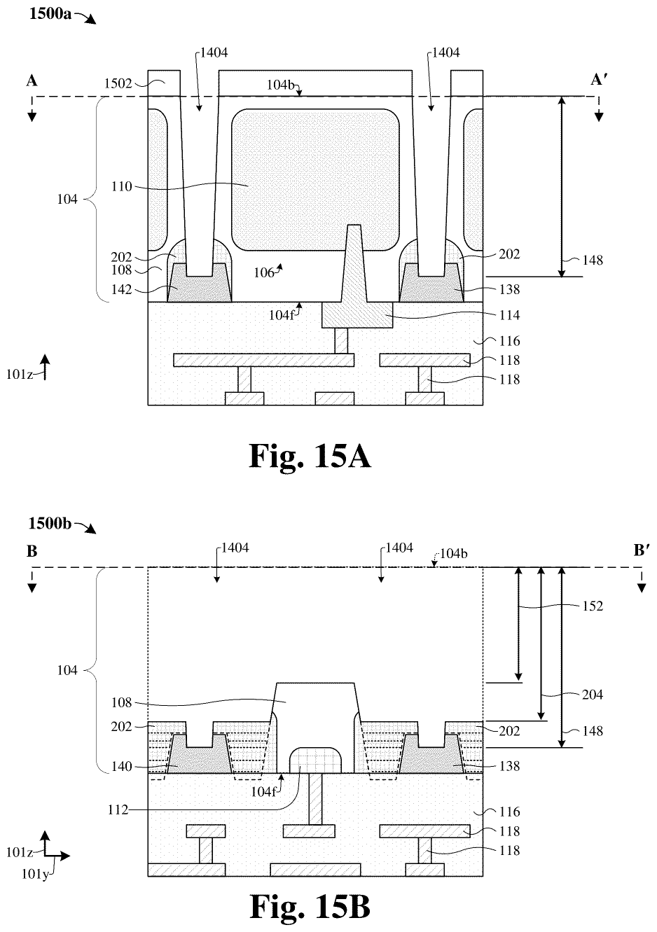

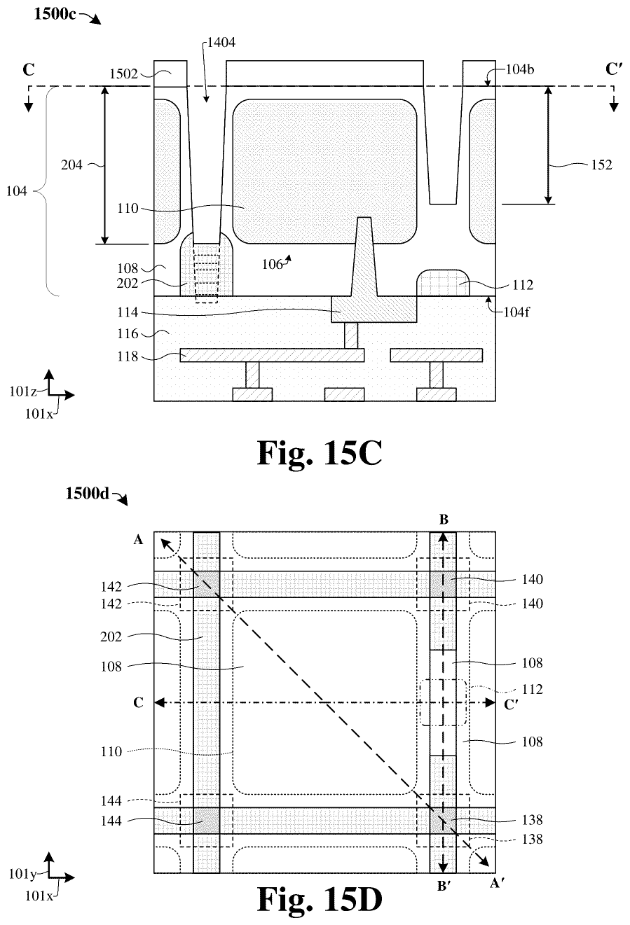

As shown in cross-sectional views 1500a, 1500b, 1500c, and top view 1500d of FIGS. 15A, 15B, 15C, 15D, respectively, the backside 104b of the substrate 104 is etched to extend the trench 1404 into the substrate 104 directly over the floating node 112 and to extend the trench 1404 further into the substrate 104 along the streets and street intersections of the trench 1404. The etching extends into the STI structures 138, 140, 142, 144 at the corners of the pixel 102 (e.g., at the intersections of streets the trench 1404) to depth 148 from the backside 104b. Along the sides of the pixel 102 (e.g., along the streets of the trench 1404), the etching extends into the isolation region 202 to at least depth 204. In some embodiments, the etching extends deeper than depth 204 along the sides of the pixel 102 (e.g., as illustrated by the dashed lines illustrated in FIGS. 15B, 15C and as explained with regard to FIG. 2C).

Again, the depth of the trench 1404 is greater at the intersections of the streets of the trench 1404 because the etching is performed along two lateral directions (e.g., along 101y and along 101x) at these intersections versus one lateral direction along the streets (e.g., along 101y or along 101x depending on the street).

The etching illustrated in FIGS. 14A-14D and FIGS. 15A-15D is performed so that the streets of the trench 1404 intersect at the STI structures 138, 140, 142, 144. The STI structures 138, 140, 142, 144 block the etching from extending through the frontside 104f of the substrate 104 at the intersections of the streets of the trench 1404 (where over-etching may be more likely to occur). The etch rate of the STI structures 138, 140, 142, 144 is substantially less than the etch rate of the substrate 104. For example, the etch rate of the STI structures 138, 140, 142, 144 is less than half of the etch rate of the substrate 104, less than a fourth of the etch rate of the substrate, or some other suitable rate. Thus, the STI structures 138, 140, 142, 144 slow the etching at the intersections of the streets of the trench 1404so that the etching extends into the STI structures but not through tops of the STI structures. Because the STI structures slow the etching at the intersections of the streets of the trenches 1404, a likelihood of over-etching at these intersections can be reduced. Thus, a likelihood of damage can be reduced.

In some embodiments, a masking layer 1502 is formed over the substrate 104 and the etching is performed according to openings in the masking layer 1502. In some embodiments, the masking layer 1502 comprises photoresist, a hard mask material, or some other suitable material. In some embodiments, the etching comprises a dry etching process or some other suitable process.

As shown in cross-sectional views 1600a, 1600b, 1600c, and top view 1600d of FIGS. 16A, 16B, 16C, 16D, respectively, the DTI structure 120 is formed in the trench 1404. In some embodiments, the DTI structure 120 is formed by depositing a second dielectric over the backside 104b and in the trench 1404 and subsequently performing a polishing or planarization process on the second dielectric to remove the second dielectric from over the backside 104b and to further delimit the DTI structure 120. In some embodiments, the second dielectric comprises silicon dioxide, aluminum oxide, or some other suitable material and is deposited by a CVD process, a PVD process, an ALD process, or some other suitable process.

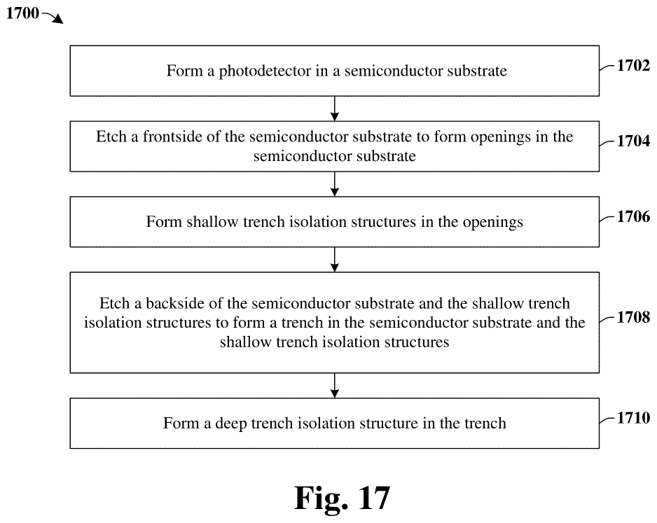

FIG. 17 illustrates a flow diagram of some embodiments of a method 1700 for forming an image sensor including STI structures on a DTI structure. While method 1700 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At block 1702, form a photodetector in a semiconductor substrate. FIGS. 10A, 10B, 10C, 10D illustrate various views 1000a, 1000b, 1000c, 1000d, respectively, of some embodiments corresponding to block 1702.

At block 1704, etch a frontside of the semiconductor substrate to form openings in the semiconductor substrate. FIGS. 11A, 11B, 11C, 11D illustrate various views 1100a, 1100b, 1100c, 1100d, respectively, of some embodiments corresponding to block 1704.

At block 1706, form shallow trench isolation structures in the openings. FIGS. 12A, 12B, 12C, 12D illustrate various views 1200a, 1200b, 1200c, 1200d, respectively, of some embodiments corresponding to block 1706.

At block 1708, etch a backside of the semiconductor substrate and the shallow trench isolation structures to form a trench in the semiconductor substrate and the shallow trench isolation structures. FIGS. 14A, 14B, 14C, 14D and FIGS. 15A, 15B, 15C, 15D illustrate various views 1400a, 1400b, 1400c, 1400d, 1500a, 1500b, 1500c, 1500d, respectively, of some embodiments corresponding to block 1708. For example, first etch, then second etch.

At block 1710, form a deep trench isolation structure in the trench. FIGS. 16A, 16B, 16C, 16D illustrate various views 1600a, 1600b, 1600c, 1600d, respectively, of some embodiments corresponding to block 1710.

Thus, the present disclosure relates to an image sensor and a method for forming the image sensor, the image sensor including STI structures directly over a DTI structure at intersections of walls of the DTI structure to block the DTI structure from extending through a front-side of the substrate at the intersections.

Accordingly, in some embodiments, the present disclosure relates to an image sensor including a photodetector in a semiconductor substrate. A floating node is in the semiconductor substrate and beside the photodetector. A transfer gate is over and between the photodetector and the floating node. A deep trench isolation (DTI) structure extends into the semiconductor substrate from a backside of the semiconductor substrate. A shallow trench isolation (STI) structure extends into the semiconductor substrate from a frontside of the semiconductor substrate and over the DTI structure. The DTI structure extends into the semiconductor substrate to a first depth from the backside. The DTI structure extends into the STI structure to a second depth from the backside different than the first depth.

In other embodiments, the present disclosure relates to an image sensor including a semiconductor substrate. A bulk region of the semiconductor substrate has a first doping type. A photodetector region of the semiconductor substrate has a second doping type different than the first doping type. A floating region of the semiconductor substrate has the second doping type and extends from a frontside of the semiconductor substrate toward a backside of the semiconductor substrate. A transfer gate is along the frontside of the semiconductor substrate. The transfer gate is over and between the photodetector region and the floating region. A deep trench isolation (DTI) structure extends into the semiconductor substrate from the backside of the semiconductor substrate toward the frontside and surrounding the photodetector region. The DTI structure has a first upper surface at a first depth from the backside of the semiconductor substrate along a first wall of the DTI structure. The DTI structure has a second upper surface at a second depth from the backside of the semiconductor substrate along an intersection of the DTI structure where the first wall and a second wall of the DTI structure intersect. The second depth is different than the first depth. A shallow trench isolation (STI) structure extends into the semiconductor substrate from the frontside of the semiconductor substrate toward the backside and over the DTI structure at the intersection of the DTI structure. The STI structure has a first lower surface at a third depth from the backside of the semiconductor substrate. The STI structure has a second lower surface on the second upper surface of the DTI structure. The third depth is less than the second depth so a lower portion of the STI structure has a vertical overlap with a first upper portion of the DTI structure.

In yet other embodiments, the present disclosure relates to a method for forming an image sensor. A photodetector region and a floating region are formed in a semiconductor substrate along a frontside of the semiconductor substrate. A bulk region of the semiconductor substrate has a first doping type. The photodetector region and the floating region have a second doping type different than the first doping type. A transfer gate is formed along the frontside of the semiconductor substrate. The transfer gate is over and between the photodetector region and the floating region. The frontside of the semiconductor substrate is etched to form a first opening in the semiconductor substrate. A first dielectric is deposited in the first opening to form a shallow trench isolation (STI) structure in the first opening. A backside of the semiconductor substrate and the STI structure are etched to form a trench in the semiconductor substrate and the STI structure and surrounding the photodetector region. A second dielectric is deposited in the trench to form a deep trench isolation (DTI) structure in the trench.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An image sensor comprising:
a photodetector in a semiconductor substrate;
a floating node in the semiconductor substrate and beside the photodetector;
a transfer gate over and between the photodetector and the floating node;
a deep trench isolation (DTI) structure extending into the semiconductor substrate from a backside of the semiconductor substrate; and
a shallow trench isolation (STI) structure extending into the semiconductor substrate from a frontside of the semiconductor substrate and over the DTI structure,
wherein the DTI structure extends into the semiconductor substrate to a first depth from the backside, and wherein the DTI structure extends into the STI structure to a second depth from the backside different than the first depth.

2. The image sensor of claim 1, wherein the DTI structure has an upper surface at the second depth, wherein the second depth is less than a thickness of the semiconductor substrate, and wherein a lower surface of the STI structure is on the upper surface of the DTI structure.

3. The image sensor of claim 1, wherein the DTI structure has an upper surface at the first depth, and wherein the first depth is approximately equal to a thickness of the semiconductor substrate and the upper surface extends along the frontside of the semiconductor substrate beside the STI structure.

4. The image sensor of claim 1, further comprising:
an isolation region in the semiconductor substrate and beside the STI structure, the isolation region extending from the frontside of the semiconductor substrate toward the backside of the semiconductor substrate and surrounding the photodetector, wherein the DTI structure extends into the isolation region to the first depth from the backside.

5. The image sensor of claim 4, wherein the DTI structure has an upper surface at the first depth, and wherein the isolation region is between the upper surface and the frontside of the semiconductor substrate, and wherein the isolation region extends along the upper surface and below the upper surface of the DTI structure along a first sidewall and a second sidewall of the DTI structure.

6. The image sensor of claim 1, wherein the DTI structure is spaced from the floating node under the floating node, and wherein the DTI structure extends into the semiconductor substrate to a third depth from the backside under the floating node, the third depth being less than the first depth and the second depth.

7. The image sensor of claim 6, wherein the DTI structure has a protrusion under the floating node which protrudes upward from the third depth toward the floating node.

8. An image sensor comprising:
a semiconductor substrate, a bulk region of the semiconductor substrate having a first doping type, a photodetector region of the semiconductor substrate having a second doping type different than the first doping type, a floating region of the semiconductor substrate having the second doping type and extending from a frontside of the semiconductor substrate toward a backside of the semiconductor substrate;
a transfer gate along the frontside of the semiconductor substrate, the transfer gate being over and between the photodetector region and the floating region;
a deep trench isolation (DTI) structure extending into the semiconductor substrate from the backside of the semiconductor substrate toward the frontside and surrounding the photodetector region, the DTI structure having a first upper surface at a first depth from the backside of the semiconductor substrate along a first wall of the DTI structure, the DTI structure having a second upper surface at a second depth from the backside of the semiconductor substrate along an intersection of the DTI structure where the first wall and a second wall of the DTI structure intersect, the second depth being different than the first depth; and
a shallow trench isolation (STI) structure extending into the semiconductor substrate from the frontside of the semiconductor substrate toward the backside and over the DTI structure at the intersection of the DTI structure, the STI structure having a first lower surface at a third depth from the backside of the semiconductor substrate, the STI structure having a second lower surface on the second upper surface of the DTI structure, the third depth being less than the second depth so a lower portion of the STI structure has a vertical overlap with a first upper portion of the DTI structure.

9. The image sensor of claim 8, an isolation region of the semiconductor substrate having the first doping type, the isolation region extending from the frontside of the semiconductor substrate toward the backside of the semiconductor substrate to a fourth depth from the backside along the first wall of the DTI structure, the fourth depth being less than the first depth so a lower portion of the isolation region has a vertical overlap with a second upper portion of the DTI structure along the first wall of the DTI structure.

10. The image sensor of claim 9, wherein the first depth is less than the third depth and the semiconductor substrate is between the first upper surface of DTI structure and the first lower surface of the STI structure.

11. The image sensor of claim 9, wherein the first depth is greater than the third depth and less than the second depth so the first upper surface of the DTI structure is above the first lower surface of the STI structure and below the second upper surface of the DTI structure, and wherein the first lower surface of the STI structure is on a third upper surface of the DTI structure.

12. The image sensor of claim 9, wherein the first depth is greater than the second depth and less than a thickness of the semiconductor substrate so the first upper surface of the DTI structure is above the second upper surface of the DTI structure and below the frontside of the semiconductor substrate, wherein the first lower surface of the STI structure is on a third upper surface of the DTI structure.

13. The image sensor of claim 8, wherein the first depth is approximately equal to a thickness of the semiconductor substrate so the first upper surface of the DTI structure extends along the frontside of the semiconductor substrate, wherein the first lower surface of the STI structure is on a third upper surface of the DTI structure.

14. The image sensor of claim 8, wherein the first depth is greater than a thickness of the semiconductor substrate so the first upper surface of the DTI structure is above the frontside of the semiconductor substrate, wherein the first lower surface of the STI structure is on a third upper surface of the DTI structure.

15. The image sensor of claim 8, the STI structure having a third lower surface at a fourth depth from the backside of the semiconductor substrate, the fourth depth being less than the second depth and the third depth so the third lower surface is below the first lower surface and the second lower surface of the STI structure.

16. A method for forming an image sensor, the method comprising:
forming a photodetector region and a floating region in a semiconductor substrate along a frontside of the semiconductor substrate, a bulk region of the semiconductor substrate having a first doping type, the photodetector region and the floating region having a second doping type different than the first doping type;
forming a transfer gate along the frontside of the semiconductor substrate, the transfer gate being over and between the photodetector region and the floating region;
etching the frontside of the semiconductor substrate to form a first opening in the semiconductor substrate;
depositing a first dielectric in the first opening to form a shallow trench isolation (STI) structure in the first opening;
etching a backside of the semiconductor substrate and the STI structure to form a trench in the semiconductor substrate and the STI structure and surrounding the photodetector region; and
depositing a second dielectric in the trench to form a deep trench isolation (DTI) structure in the trench.

17. The method of claim 16, wherein an etch rate of the STI structure is substantially less than an etch rate of the semiconductor substrate during the etching of the backside of the semiconductor substrate and the STI structure.

18. The method of claim 17, wherein the backside of the semiconductor substrate and the STI structure are laterally etched in a first direction to form a first trench street and laterally etched in a second direction, transverse to the first direction, to form a second trench street, and wherein the backside of the semiconductor substrate and the STI structure are etched so the first trench street and the second trench street intersect at the STI structure.

19. The method of claim 16, further comprising:
forming an isolation region in the semiconductor substrate along the frontside of the semiconductor substrate, the isolation region having the first doping type, wherein the etching of the backside of the semiconductor substrate extends the trench extends into the isolation region.

20. The method of claim 16, wherein the backside of the semiconductor substrate and the STI structure are etched with a first etching process and a second etching process after the first etching process, wherein a masking layer is over the floating region during the first etching process and the masking layer is removed from over the floating region during the second etching process.
